(19) United States
(12) Patent Application Publication
(10) Pub. No.: US 2026/0040696 A1
(43) Pub. Date: Feb. 5, 2026

(54) PHOTODETECTOR

(71) Applicant: SHARP KABUSHIKI KAISHA, Sakai City (JP)

(72) Inventors: TADAYOSHI MIYAMOTO, Sakai City (JP); Fumiki Nakano, Sakai City (JP)

(21) Appl. No.: 19/285,065

(22) Filed: Jul. 30, 2025

(30) Foreign Application Priority Data
Aug. 2, 2024 (JP) 2024-128220

(51) Int. Cl. H10F 30/298; H10F 39/10; H10F 77/12

(52) U.S. Cl. CPC H10F 30/298; H10F 39/103; H10F 77/12

(57) ABSTRACT

A photodetector includes a first thin-film transistor configured to convert light into an electric signal. The first TFT includes a first gate electrode, a first source electrode, a first drain electrode, and a first oxide semiconductor film striding between the first source electrode and the first drain electrode. The first gate electrode and the first source electrode are electrically connected to each other.

### CROSS REFERENCE TO RELATED APPLICATION

The present application claims priority from Japanese Application JP2024-128220, filed on Aug. 2, 2024, the content of which is hereby incorporated by reference into this application.

### BACKGROUND

### Field of the Disclosure

The present disclosure relates to a photodetector including thin-film transistors.

### Description of the Related Art

Flat-panel photodetectors in which photodiodes that convert light into electric charges, and thin-film transistors (TFTs) that function as switching elements are arranged in matrix have been widely used as image sensors, photosensors, and other things. Japanese Unexamined Patent Application Publication No. 2013-156119 discloses an example radiographic imaging device including such a photodetector.

Japanese Unexamined Patent Application Publication No. 2013-156119 discloses that a semiconductor film included in a TFT may be formed from an oxide semiconductor, such as indium gallium zinc oxide (InGaZnO) or zinc oxide (ZnO). Oxide semiconductors have lower leakage current than the other semiconductors.

However, such a photodiode as that used in the photodetector of Japanese Unexamined Patent Application Publication No. 2013-156119 needs area increase of the photodiode in order to obtain a required sensitivity. Hence, it is unfortunately difficult to produce a high-definition photodetector.

### SUMMARY

An object of one aspect of the present disclosure is to achieve a photodetector with high definition.

To solve the above problem, a photodetector according to one aspect of the present disclosure includes a first thin-film transistor (TFT) configured to convert light into an electric signal. The first TFT includes a first gate electrode, a first source electrode, a first drain electrode, and a first oxide semiconductor film striding between the first source electrode and the first drain electrode. The first gate electrode and the first source electrode are electrically connected to each other.

The aspect of the present disclosure can achieve a photodetector with high definition.

### BRIEF DESCRIPTION OF THE DRAWINGS

FIG. 1 is a schematic cross-sectional view of a photodetector according to one embodiment;

FIG. 2 is graphs showing change in the relationship between voltage and current when a TFT according to a comparative example and a first TFT included in the photodetector according to the embodiment of the present disclosure are individually irradiated with X-rays;

FIG. 3 illustrates the first TFT and a second TFT in plan view; and

FIG. 4 is graphs showing the relationship between gate voltage and drain current in the first and second TFTs illustrated in FIG. 3.

### DETAILED DESCRIPTION OF THE DISCLOSURE

One embodiment of the present disclosure will be detailed.

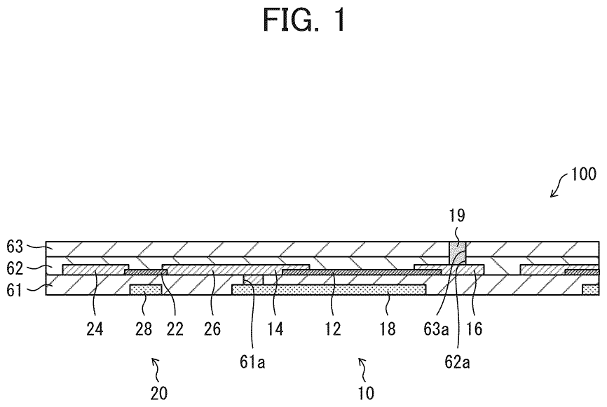

FIG. 1 is a schematic cross-sectional view of a photodetector 100 according to one embodiment of the present disclosure. The photodetector 100 is a flat-panel photodetector for instance, and is, for example, a photosensor, an image sensor, or a radiation detecting device (X-ray imaging display device), but is not limited thereto. As illustrated in FIG. 1, the photodetector 100 includes a first thin-film transistor (TFT) 10 and a second TFT 20. The first TFT 10 and the second TFT 20 are formed on a substrate not shown.

The first TFT 10 converts light into an electric signal. The first TFT 10 includes a first source electrode 14, a first drain electrode 16, and a first oxide semiconductor film 12 striding between the first source electrode 14 and the first drain electrode 16, and a first gate electrode 18 that controls current in the first oxide semiconductor film 12. The first TFT 10 further includes a wiring layer 19 for applying a bias to the first drain electrode 16.

The first gate electrode 18 and the first source electrode 14 are electrically connected to each other. Thus, the first TFT 10 functions like a two-terminal diode. To be specific, the first gate electrode 18 and the first source electrode 14 function as a cathode terminal of the two-terminal diode. In addition, the first drain electrode 16 functions as an anode terminal of the two-terminal diode.

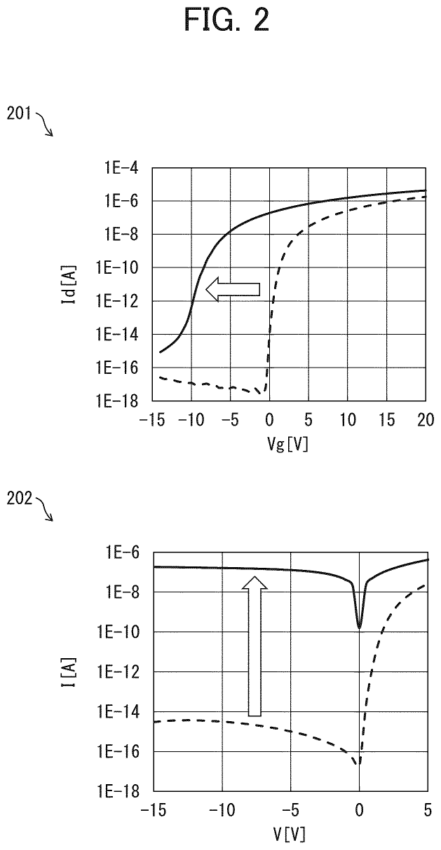

FIG. 2 is graphs showing change in the relationship between voltage and current when a TFT according to a comparative example and the first TFT 10 are individually irradiated with X-rays. The TFT according to the comparative example has the same configuration as that of the first TFT 10 with the exception that the first gate electrode 18 and the first source electrode 14 are not electrically connected to each other. In FIG. 2, Symbol 201 shows the relationship between a gate voltage Vg (V) and a drain current Id (A) in the TFT according to the comparative example. Symbol 202 shows the relationship between a voltage V and a current I in the first TFT 10. The expression of gate voltage and drain current is not appropriate in the first TFT 10, in which the first gate electrode 18 and the first source electrode 14 are electrically connected to each other; accordingly, voltage and current are merely used. In both of Symbols 201 and 202, the graphs before X-ray irradiation are denoted by broken lines, and the graphs after the X-ray irradiation are denoted by solid lines.

As shown by Symbol 201, irradiating the TFT according to the comparative example with X-rays shifts threshold voltage to a negative direction. The threshold voltage herein is the gate voltage Vg when the drain current Id becomes a predetermined value. The predetermined value of the drain current Id is 1 nA for instance. This threshold voltage shift means increase in leakage current.

As shown by Symbol 202, X-ray irradiation changes the V-I relationship also in the first TFT 10, in which the first gate electrode 18 and the first source electrode 14 are electrically connected to each other. In the example shown by Symbol 202, it can be more clearly seen that the leakage current increases. That is, it can be said that light (X-rays) is converted into an electric signal (leakage current) by the first TFT 10. It is considered that detection of such a leakage current amount in the first TFT 10 is based on the same principle as detection of a light leakage amount in a photodiode.

Irradiating the first TFT 10 or second TFT 20 with ionization radiations including X-rays generates electron-and-hole pairs within a gate insulating film 61. Among them, the electrons are emitted from the gate insulating film 61 in a short time. On the other hand, holes have smaller mobility than electrons. Thus, some of the holes within the gate insulating film 61 are trapped near the interface between the gate insulating film 61 and first oxide semiconductor film 12 and the interface between the gate insulating film 61 and second oxide semiconductor film 22, to turn into fixed positive electric charges. It is considered that the fixed positive electric charges within the gate insulating film 61 cause change in Vth.

The second TFT 20 detects the electric signal converted by the first TFT 10. To be specific, the second TFT 20 is a switching element that undergoes switching in accordance with the electric signal converted by the first TFT 10. The second TFT 20 includes a second source electrode 24, a second drain electrode 26, and a second oxide semiconductor film 22 striding between the second source electrode 24 and the second drain electrode 26, and a second gate electrode 28 that controls current in the second oxide semiconductor film 22.

The first source electrode 14 and the second drain electrode 26 are electrically connected to each other. This enables the second TFT 20 to detect the electric signal converted by the first TFT 10. In the example illustrated in FIG. 1, the first source electrode 14 and the second drain electrode 26 are formed integrally. Further, the first gate electrode 18 and the first source electrode 14 are electrically connected to each other, as earlier described. The first gate electrode 18 and the second drain electrode 26 are thus electrically connected to each other via the first source electrode 14.

The first gate electrode 18 and the second gate electrode 28 may be formed in an identical layer using an identical material. Further, the first oxide semiconductor film 12 and the second oxide semiconductor film 22 may be formed in an identical layer using an identical oxide semiconductor material. Furthermore, the first source electrode 14, the first drain electrode 16, the second source electrode 24, and the second drain electrode 26 may be formed in an identical layer using an identical material. Accordingly, the first TFT 10 and the second TFT 20 can be formed in the same process step, which will be described later on. This reduces damage to the second TFT 20 during the formation of the first TFT 10 when compared to, for instance, an instance where the first TFT 10 is formed after the second TFT 20 is formed.

The oxide semiconductor material of the first oxide semiconductor film 12 and second oxide semiconductor film 22 may contain at least one element selected from In, Ga, or Zn. This enables the photodetector 100 to have higher sensitivity and to be smaller than a photodetector in which the oxide semiconductor material is an oxide semiconductor material other than the foregoing. Nevertheless, the oxide semiconductor material in the photodetector 100 may contain none of In, Ga, and Zn.

The photodetector 100 further includes the gate insulating film 61. The gate insulating film 61 is an insulating film covering the first gate electrode 18 and the second gate electrode 28. Note that the gate insulating film 61 includes a contact hole 61a. The first gate electrode 18 and the first source electrode 14 are electrically connected to each other via the contact hole 61a.

The photodetector 100 further includes a first passivation film 62 and a second passivation film 63. The first passivation film 62 is an insulating film covering the first TFT 10 and the second TFT 20. The second passivation film 63 is an insulating film covering the first passivation film 62.

The first passivation film 62 includes a contact hole 62a. The second passivation film 63 includes a contact hole 63a. The contact holes 62a and 63a overlap each other in plan view. The wiring layer 19 is exposed to the outside of the photodetector 100 via the contact holes 62a and 63a.

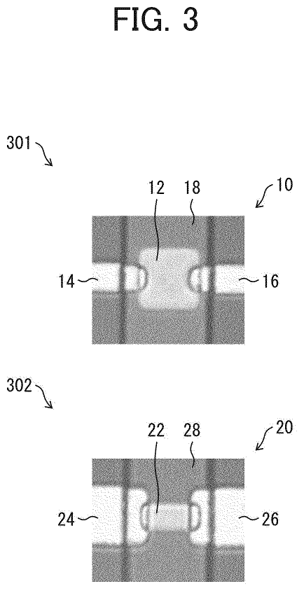

FIG. 3 illustrates the first TFT 10 and second TFT 20 in plan view. In FIG. 3, Symbol 301 shows the first TFT 10 in a plan view from a direction perpendicular to the first oxide semiconductor film 12 and second oxide semiconductor film 22, and Symbol 302 shows the second TFT 20 in this plan view.

As illustrated in FIG. 3, the first oxide semiconductor film 12 may have a larger size than the second oxide semiconductor film 22 in the plan view. For instance, the first oxide semiconductor film 12 may measure 8 μm in each of height and width. On the other hand, the second oxide semiconductor film 22 may measure 8 μm in height, and 4 μm in width. The height herein is a direction from the first source electrode 14 to the first drain electrode 16 in a plan view, and a direction from the second source electrode 24 to the second drain electrode 26 in the plan view. In addition, the width herein is a direction perpendicular to the height in the plan view. However, the sizes of the first oxide semiconductor film 12 and second oxide semiconductor film 22 are not limited to these measurements.

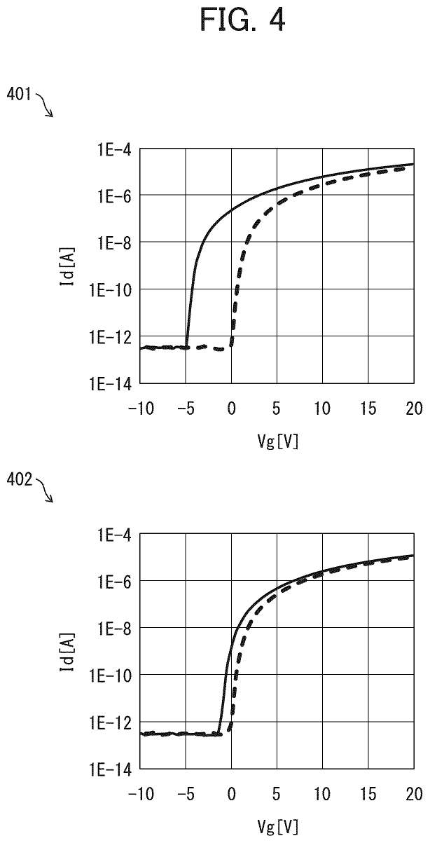

FIG. 4 is graphs showing the relationship between the gate voltage Vg and drain current Id in the first TFT 10 and second TFT 20 illustrated in FIG. 3. In FIG. 4, Symbol 401 shows the Vg-Id relationship in the first TFT 10, and Symbol 402 shows the Vg-Id relationship in the second TFT 20. The Vg-Id relationship shown by Symbol 401 is that in an instance where the first source electrode 14 and first gate electrode 18 are not electrically connected to each other in the first TFT 10. In both of Symbols 401 and 402, the graphs before X-ray irradiation are denoted by broken lines, and the graphs after the X-ray irradiation are denoted by solid lines.

In FIG. 4, the first TFT 10 exhibits a larger threshold voltage change caused by the X-ray irradiation than the second TFT 20. This is because that the first oxide semiconductor film 12 has a larger size than the second oxide semiconductor film 22 in plan view. In a TFT including an oxide semiconductor film, the interface between the oxide semiconductor film and gate insulating film has a larger area, thus exerting a larger influence caused by X-ray irradiation to the TFT, along with increase in the size of the oxide semiconductor film in plan view. Accordingly, specifying the sizes of the first oxide semiconductor film 12 and second oxide semiconductor film 22 at the foregoing measurements can improve the sensitivity of the first TFT 10 to X-rays, and reduce the X-ray influence on the second TFT 20.

Further, photodiodes, which need to receive X-rays to covert them into electrons, require area for the X-ray reception. Thus, a photodiode in a known photodetector that detects light by using the photodiode has a size of, for instance, 150 μm in each of height and width. In contrast to this, the first TFT 10, which can detect X-rays directly, can measure 8 μm in each of height and width, as earlier described. As such, providing the photodetector 100 with the first TFT 10 instead of a photodiode can downsize a light detecting element.

In particular, the photodetector 100, which includes the first gate electrode 18 and first source electrode 14 electrically connected to each other, needs no wiring line for voltage application to the first gate electrode 18. Accordingly, a space for such a wiring line is unnecessary, enabling the photodetector 100 with high definition.

### Manufacturing Method

The following describes a method for manufacturing the photodetector 100. The first process step is forming a 50- to 500-nm thick conductive film that is to be the first gate electrode 18 and the second gate electrode 28 onto a substrate.

Examples of the substrate include a glass substrate, a silicon substrate, and a heat-resistant plastic substrate. As the plastic substrate in particular, a polyethylene terephthalate (PET) substrate, a polyethylene naphthalate (PEN) substrate, a polyethersulfone (PES) substrate, an acrylic substrate, a polyimide substrate, or substrates of other materials can be used.

As the conductive film, a film of metal, such as aluminum (Al), tungsten (W), molybdenum (Mo), tantalum (Ta), chromium (Cr), titanium (Ti), or copper (Cu), of alloy thereof, or of metal nitride thereof can be appropriately used. Further, two or more of them may be stacked as the conductive film. For instance, a 370-nm thick film of W is formed onto the substrate, followed by a 50-nm thick film of TaN to form the first gate electrode 18 and second gate electrode 28 each having a stack of W and TaN (W/TaN=370 nm/50 nm). To be specific, W and TaN are evaporated onto the substrate through sputtering to form a film thereof, followed by photolithography through dry etching to form the first gate electrode 18 and the second gate electrode 28 each having a desired shape.

The next is forming the gate insulating film 61 onto the first gate electrode 18 and the second gate electrode 28. The gate insulating film 61 may have a two-ply layer structure. As the gate insulating film 61, silicon oxide (SiOₓ), silicon nitride (SiNₓ), silicon oxynitride (SiOₓN_{y}, where x>y is established), silicon nitride oxide (SiNₓO_{y}, where x>y is established), or other materials can be used as appropriate. When the gate insulating film 61 has a two-ply layer structure, the lower gate insulating film located closer to the first gate electrode 18 and second gate electrode 28 may be formed using, but not limited to, SiNₓ or SiNₓO_{y} (where x>y is established) in order to avoid diffusion of impurities and other things from the substrate. In addition, the upper gate insulating film located opposite the first gate electrode 18 and second gate electrode 28 may be formed using, but not limited to, SiOₓ or silicon oxynitride (SiOₓN_{y}, where x>y is established).

A dense insulating film can be formed at a relatively low temperature by mixing a rare gas, such as argon, into a reaction gas that is used for forming the gate insulating film 61, and by mixing the rare gas into the gate insulating film 61. Forming a dense insulating film as the gate insulating film 61 can reduce leakage current.

For instance, a 325-nm thick SiN film is deposited as a lower layer by using a chemical vapor deposition (CVD) apparatus. Furthermore, a 10-nm thick SiO₂ film is sequentially deposited as an upper layer thereonto to form an insulating film of two-ply layer structure that is to be the gate insulating film 61. At this time point, since the contact hole 61a is not provided in the gate insulating film 61, the gate insulating film 61 is incomplete. However, for simplification, the insulating film without the contact hole 61a is also referred to as the gate insulating film 61 in the following description.

The first oxide semiconductor film 12 and the second oxide semiconductor film 22 each having a thickness of 30 to 100 nm are formed onto the gate insulating film 61. The first oxide semiconductor film 12 and the second oxide semiconductor film 22 may be formed from, but not limited to, an InGaZnO semiconductor, as earlier described. To be specific, InGaO₃ (ZnO)₅, magnesium zinc oxide (MgₓZn₁₋ₓO), cadmium zinc oxide (CdₓZn₁₋ₓO), cadmium oxide (CdO), or an In—Ga—Zn—O amorphous oxide semiconductor (a-InGaZnO) can be used as the material of the first oxide semiconductor film 12 and second oxide semiconductor film 22. Alternatively, ZnO to which one or more kinds of impurity elements from among group 1 elements, group 13 elements, group 14 elements, group 15 elements, group 17 elements, and others are added can be used as the material of the first oxide semiconductor film 12 and second oxide semiconductor film 22. In this case, the ZnO may be amorphous ZnO, polycrystalline ZnO, or microcrystalline ZnO with a mixture of amorphous and polycrystalline ZnO. Furthermore, ZnO to which no impurity elements are added can be used as the material of the first oxide semiconductor film 12 and second oxide semiconductor film 22.

For example, an oxide semiconductor film that is to be the first oxide semiconductor film 12 and the second oxide semiconductor film 22 is formed through sputtering. The next is photolithography using dry etching to form the first oxide semiconductor film 12 and the second oxide semiconductor film 22 each having a desired shape.

After the first oxide semiconductor film 12 and the second oxide semiconductor film 22 are formed, the contact hole 61a is provided in the gate insulating film 61. To be specific, photolithography using dry etching is performed to provide the contact hole 61a in a part of the gate insulating film 61 overlapping the first gate electrode 18. This completes the gate insulating film 61.

The first source electrode 14, the first drain electrode 16, the second source electrode 24, and the second drain electrode 26 are formed onto the first oxide semiconductor film 12 and the second oxide semiconductor film 22. To be specific, a conductive film is formed onto the gate insulating film 61, the first oxide semiconductor film 12, and the second oxide semiconductor film 22. Furthermore, the conductive film is processed into a desired shape through photolithography using a resist mask to form the first drain electrode 16, the second source electrode 24, and the second drain electrode 26. As the conductive film, metal, such as aluminum (Al), tungsten (W), molybdenum (Mo), tantalum (Ta), copper (Cu), chromium (Cr), or titanium (Ti), alloy thereof, or metal nitride thereof can be appropriately used. Here, a Ti film, an Al film, and a Ti film respectively having thicknesses of 100 nm, 300 nm, and 30 nm are formed through sputtering, followed by photolithography using dry etching to form the first source electrode 14, the first drain electrode 16, the second source electrode 24, and the second drain electrode 26 each having a desired shape. Through the foregoing process steps, the first TFT 10 and the second TFT 20 are formed.

The first passivation film 62 is formed with a thickness of 200 to 300 nm so as to cover the first TFT 10 and the second TFT 20. The first passivation film 62 may be formed by using a thin-film formation method, such as plasma CVD or sputtering. The first passivation film 62 can be made of insulating material, such as silicon nitride, silicon oxide, silicon nitride oxide, or silicon oxynitride.

To be specific, a thin film of insulating material that is to be the first passivation film 62 is formed so as to cover the first TFT 10 and the second TFT 20. Thereafter, the contact hole 62a is formed through photolithography using dry etching, thus forming the first passivation film 62.

Furthermore, the second passivation film 63 is formed with a thickness of 200 to 300 nm onto the first passivation film 62. The second passivation film 63 may be formed by using a thin-film formation method, such as plasma CVD or sputtering, like the first passivation film 62. Further, the second passivation film 63 can be made of insulating material, such as silicon nitride, silicon oxide, silicon nitride oxide, or silicon oxynitride, like the first passivation film 62. The second passivation film 63 may or may not be made of the same material as that of the first passivation film 62.

To be specific, a thin film of insulating material that is to be the second passivation film 63 is formed so as to cover the first passivation film 62. Thereafter, the contact hole 63a is formed through photolithography using dry etching, thus forming the second passivation film 63.

It is noted that the contact hole 62a may not be formed immediately after the formation of the thin film of insulating material that is to be the first passivation film 62. In this case, the contact holes 62a and 63a may be formed sequentially after the further formation of the thin film of insulating material that is to be the second passivation film 63.

The photodetector 100 in the example illustrated in FIG. 1 includes two passivation films, i.e., the first passivation film 62 and the second passivation film 63. However, the photodetector 100 may include only the first passivation film 62, or may further include another passivation film different from the first passivation film 62 and the second passivation film 63. Further, the entire substrate may further undergo heating after the first passivation film 62 and the second passivation film 63 are formed. The heating is performed until, for instance, the substrate reaches 350° C.

The wiring layer 19 is formed in the first passivation film 62 and the second passivation film 63 through, for instance, sputtering or photolithography. The wiring layer 19 is formed from, but not limited to, Mo or Ti. The photodetector 100 can be manufactured through the foregoing process steps.

The present disclosure is not limited to the foregoing embodiments. Various modifications can be made within the scope of the claims. An embodiment that is obtained in combination as appropriate with the technical means disclosed in the respective embodiments is also included in the technical scope of the present disclosure. Furthermore, combining the technical means disclosed in the respective embodiments can form a new technical feature.

While there have been described what are at present considered to be certain embodiments of the disclosure, it will be understood that various modifications may be made thereto, and it is intended that the appended claim cover all such modifications as fall within the true spirit and scope of the disclosure.

What is claimed is:

1. A photodetector comprising a first thin-film transistor (TFT) configured to convert light into an electric signal,
wherein the first TFT includes
a first gate electrode,
a first source electrode,
a first drain electrode, and
a first oxide semiconductor film striding between the first source electrode and the first drain electrode, and
wherein the first gate electrode and the first source electrode are electrically connected to each other.

2. The photodetector according to claim 1, further comprising a second TFT configured to detect the electric signal,
wherein the second TFT includes
a second gate electrode,
a second source electrode,
a second drain electrode, and
a second oxide semiconductor film striding between the second source electrode and the second drain electrode, and
wherein the first gate electrode, the first source electrode, and the second drain electrode are electrically connected to each other.

3. The photodetector according to claim 2, wherein
the first gate electrode and the second gate electrode are formed in an identical layer using an identical material,
the first oxide semiconductor film and the second oxide semiconductor film are formed in an identical layer using an identical oxide semiconductor material, and
the first source electrode, the first drain electrode, the second source electrode, and the second drain electrode are formed in an identical layer using an identical material.

4. The photodetector according to claim 3, wherein the oxide semiconductor material contains at least one element selected from In, Ga, or Zn.

5. The photodetector according to claim 2, wherein the first oxide semiconductor film has a larger size than the second oxide semiconductor film.
